(19) United States
(12) Patent Application Publication
(10) Pub. No.: US 2025/0359436 A1
(43) Pub. Date: Nov. 20, 2025

(54) DISPLAY DEVICE

(71) Applicant: Samsung Display Co., LTD., Yongin-si (KR)

(72) Inventor: Seung Ki SONG, Yongin-si (KR)

(21) Appl. No.: 19/030,840

(22) Filed: Jan. 17, 2025

(30) Foreign Application Priority Data
May 17, 2024 (KR) 10-2024-0064569

(51) Int. Cl. H10K 59/122; G02B 27/01

(52) U.S. Cl. CPC H10K 59/122; G02B 27/0172; G02B 2027/0132; G02B 2027/0178

(57) ABSTRACT

A display device is provided in which color mixing between adjacent emission areas that provide light of different respective colors may be prevented and disconnection of a cathode electrode on adjacent emission areas that provide light of the same color may be prevented and an electronic device including the display device. The display device includes: a substrate; a plurality of first electrodes disposed on the substrate; a pixel defining film disposed on the plurality of first electrodes and defining a plurality of emission areas respectively overlapping the plurality of first electrodes, wherein the pixel defining film is disposed on a plurality of trenches adjacent to the plurality of emission areas; a light emitting stack disposed on the plurality of first electrodes and overlapping the plurality of emission areas; and a second electrode disposed on the light emitting stack. The plurality of trenches each include a first sub-trench and a second sub-trench that have different respective widths.

This application claims priority to Korean Patent Application No. 10-2024-0064569, filed on May 17, 2024, and all the benefits accruing therefrom under 35 U.S.C. § 119, the content of which in its entirety is herein incorporated by reference.

### BACKGROUND

### 1. Technical Field

The present disclosure relates to a display device an electronic device, and more particularly, to a display device in which color mixing between adjacent emission areas that provide light of different respective colors may be prevented and disconnection of a cathode electrode on adjacent emission areas that provide light of the same color may be prevented.

### 2. Description of the Related Art

A head mounted display (HMD) is an image display device that is worn on a user's head in the form of glasses or a helmet and forms a focus at a distance close to user's eyes in front of the user's eyes. The head mounted display may implement virtual reality (VR) or augmented reality (AR).

The head mounted display magnifies and displays an image displayed by a small display device using a plurality of lenses. Therefore, it may be desired for a display device applied to the head mounted display to provide a high-resolution image, for example, an image having a resolution of 3000 pixels per inch (PPI) or more. To this end, an organic light emitting diode on silicon (OLEDoS), which is a small organic light emitting display device having a high resolution, has been used as the display device applied to the head mounted display. The OLEDoS is a device that displays an image by disposing organic light emitting diodes (OLEDs) on a semiconductor wafer substrate on which complementary metal oxide semiconductors (CMOSs) are disposed.

### SUMMARY

Aspects of the present disclosure provide a display device in which color mixing between adjacent emission areas that provide light of different respective colors may be prevented and disconnection of a cathode electrode on adjacent emission areas that provide light of the same color may be prevented.

According to an aspect of the present disclosure, there is provided a display device including: a substrate; a plurality of first electrodes disposed on the substrate; a pixel defining film disposed on the plurality of first electrodes and defining a plurality of emission areas respectively overlapping the plurality of first electrodes, wherein the pixel defining film is disposed on a plurality of trenches adjacent to the plurality of emission areas; a light emitting stack disposed on the plurality of first electrodes and overlapping the plurality of emission areas; and a second electrode disposed on the light emitting stack, wherein the plurality of trenches each include a first sub-trench and a second sub-trench that have different respective widths, the first sub-trench is disposed between adjacent emission areas that provide light of different respective colors, and the second sub-trench is disposed between adjacent emission areas that provide light of a same color.

A width of the first sub-trench may be greater than a width of the second sub-trench.

The light emitting stack and the second electrode may be disconnected at the first sub-trench.

The light emitting stack and the second electrode may not be disconnected at the second sub-trench.

The plurality of emission areas may include a first emission area, a second emission area, and a third emission area that provide light of different respective colors.

The plurality of trenches may include: a first trench surrounding the first emission area; a second trench adjacent to the first emission area and surrounding the second emission area; and a third trench adjacent to the first emission area and the second emission area and surrounding the third emission area.

The first sub-trench of the first trench may be disposed between the first emission area and the second emission area.

The first sub-trench of the first trench may be disposed between the first emission area and the third emission area.

The second sub-trench of the first trench may be disposed between the first emission area and another first emission area adjacent to the first emission area.

The first trench may have a polygonal shape, and the first sub-trench of the first trench may be disposed at a side of the first trench.

The first trench may have a polygonal shape, and the second sub-trench of the first trench may be disposed at a corner of the first trench.

The first sub-trench of the second trench may be disposed between the second emission area and the first emission area.

The first sub-trench of the second trench may be disposed between the second emission area and the third emission area.

The second sub-trench of the second trench may be disposed between the second emission area and another second emission area adjacent to the second emission area.

The second trench may have a polygonal shape, and the first sub-trench of the second trench may be disposed at a side of the second trench.

The second trench may have a polygonal shape, and the second sub-trench of the second trench may be disposed at a corner of the second trench.

The first sub-trench of the third trench may be disposed between the third emission area and the first emission area.

The first sub-trench of the third trench may be disposed between the third emission area and the second emission area.

The second sub-trench of the third trench may be disposed between the third emission area and another third emission area adjacent to the third emission area.

The third trench may have a polygonal shape, and the first sub-trench of the third trench may be disposed at a side of the third trench.

The third trench may have a polygonal shape, and the second sub-trench of the third trench may be disposed at a corner of the third trench.

The first sub-trench may have a rectangular shape.

The second sub-trench may have a bent shape.

The first sub-trench may have a bent shape, and the first sub-trench may have one bent portion.

The second sub-trench may have a bent shape, and the second sub-trench may have two bent portions.

According to an aspect of the present disclosure, there is provided an electronic device comprising a display device including a screen: wherein the display device includes: a substrate; a plurality of first electrodes disposed on the substrate; a pixel defining film disposed on the plurality of first electrodes and defining a plurality of emission areas respectively overlapping the plurality of first electrodes, wherein the pixel defining film is disposed on a plurality of trenches adjacent to the plurality of emission areas; a light emitting stack disposed on the plurality of first electrodes and overlapping the plurality of emission areas; and a second electrode disposed on the light emitting stack. The plurality of trenches each include a first sub-trench and a second sub-trench that have different respective widths.

With a display device according to the present disclosure, color mixing between adjacent emission areas that provide light of different respective colors may be prevented and disconnection of a cathode electrode on adjacent emission areas that provide light of the same color may be prevented.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view illustrating a display device according to an example embodiment;

FIG. 2 is a block diagram illustrating the display device according to an example embodiment;

FIG. 3 is an equivalent circuit diagram of a first pixel according to an example embodiment;

FIG. 4 is a layout diagram illustrating an example of a display panel according to an example embodiment;

FIGS. 5 and 6 are layout diagrams illustrating example embodiments of a display area of FIG. 4;

FIG. 7 is a cross-sectional view illustrating an example of the display panel taken along line I1-I1′ of FIG. 5;

FIG. 8 is a layout diagram illustrating another example embodiment of the display area of FIG. 4;

FIG. 9 is a cross-sectional view illustrating an example embodiment of the display panel taken along line I1-I1′ of FIG. 8;

FIG. 10 is a layout diagram illustrating still another example embodiment of the display area of FIG. 4;

FIG. 11 is a perspective view illustrating a head mounted display according to an example embodiment;

FIG. 12 is an exploded perspective view illustrating an example of the head mounted display of FIG. 11; and

FIG. 13 is a perspective view illustrating a head mounted display according to another example embodiment.

### DETAILED DESCRIPTION

Aspects supported by the present disclosure will now be described more fully hereinafter with reference to the accompanying drawings, in which example embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, and the like may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not necessarily require or imply the presence of a second element or other elements. The terms “first”, “second”, and the like may also be used herein to differentiate different categories or sets of elements. For conciseness, the terms “first”, “second”, and the like may represent “first-category (or first-set)”, “second-category (or second-set)”, and the like, respectively.

Features of various embodiments of the present disclosure may be combined partially or totally. As will be clearly appreciated by those skilled in the art, technically various interactions and operations are possible. Various embodiments can be practiced individually or in combination.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Hereinafter, specific example embodiments will be described with reference to the accompanying drawings.

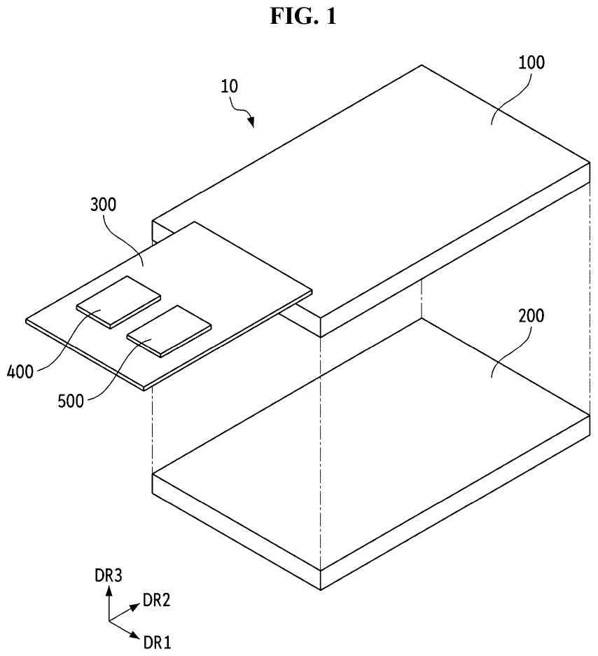

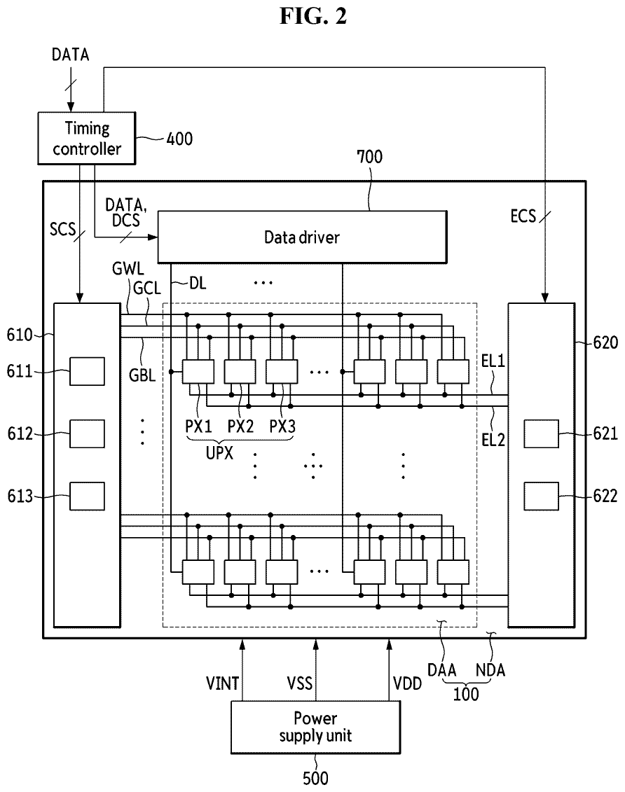

FIG. 1 is an exploded perspective view illustrating a display device according to an example embodiment. FIG. 2 is a block diagram illustrating the display device according to an example embodiment.

Referring to FIGS. 1 and 2, a display device 10 according to an example embodiment is a device that displays a moving image or a still image. The display device 10 according to an example embodiment may be applied to portable electronic devices such as, for example, mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according an example embodiment may be applied as a display unit of televisions, laptop computers, monitors, billboards, or the Internet of Things (IOTs). Alternatively, the display device 10 according an example embodiment may be applied to smart watches, watch phones, or head mounted displays (HMDs) for implementing virtual reality and augmented reality.

The display device 10 according to an example embodiment includes a display panel 100, a heat dissipation layer 200, a circuit board 300, a timing controller 400, and a power supply unit 500.

The display panel 100 may have a shape similar to a rectangular shape in plan view. For example, the display panel 100 may have a shape similar to a rectangular shape, in plan view, having short sides in a first direction DR1 and long sides in a second direction DR2 crossing the first direction DR1. In the display panel 100, a corner where the short side in the first direction DR1 and the long side in the second direction DR2 meet may be rounded with a predetermined curvature or right-angled. A shape of the display panel 100 in plan view is not limited to the rectangular shape, and may be a shape similar to other polygonal shapes, a circular shape, or an elliptical shape. A shape of the display device 10 in plan view may follow the shape of the display panel 100 in plan view, but embodiments of the present disclosure are not limited thereto.

The display panel 100 may include a display area DAA that displays an image and a non-display area NDA that does not display an image, as illustrated in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines EL1 and a plurality of second emission control lines EL2.

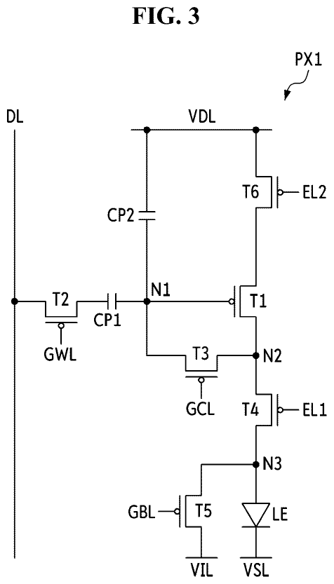

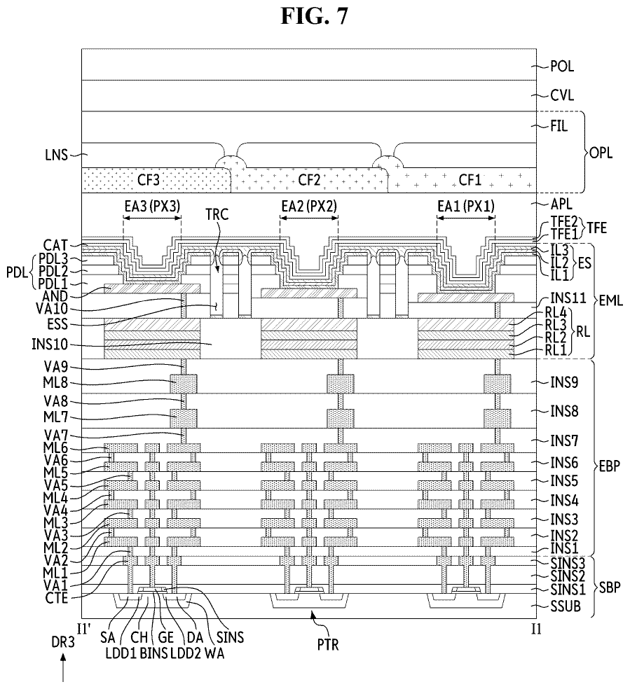

A plurality of unit pixels UPX include a plurality of pixels PX1, PX2, and PX3. The plurality of pixels PX1, PX2, and PX3 may include a plurality of pixel transistors as illustrated in FIG. 3, and the plurality of pixel transistors may be formed by a semiconductor process and disposed on a semiconductor substrate SSUB (see FIG. 7). For example, a plurality of pixel transistors of a data driver 700 may be formed as complementary metal oxide semiconductors (CMOSs).

Each of the plurality of pixels PX1, PX2, and PX3 may be connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of pixels PX1, PX2, and PX3 may receive a data voltage of the data line DL according to a write scan signal of the write scan line GWL, and allow a light emitting element to emit light according to the data voltage.

The non-display area NDA includes a scan driver 610, an emission driver 620, and a data driver 700.

The scan driver 610 includes a plurality of scan transistors, and the emission driver 620 includes a plurality of light emitting transistors. The plurality of scan transistors and the plurality of light emitting transistors may be formed by a semiconductor process and formed on a semiconductor substrate SSUB (see FIG. 7). For example, the plurality of scan transistors and the plurality of light emitting transistors may be formed as CMOSs. It has been illustrated in FIG. 2 that the scan driver 610 is disposed on the left side of the display area DAA and the emission driver 620 is disposed on the right side of the display area DAA, but embodiments of the present disclosure are not limited thereto. For example, the scan drivers 610 and the emission drivers 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed by a semiconductor process and formed on a semiconductor substrate SSUB (see FIG. 7). For example, the plurality of data transistors may be formed as CMOSs.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this case, the pixels PX1, PX2, and PX3 may be selected by the write scan signals of the scan driver 610, and the data voltages may be supplied to the selected pixels PX1, PX2, and PX3.

The heat dissipation layer 200 may overlap the display panel 100 in a third direction DR3, which is a thickness direction of the display panel 100. The heat dissipation layer 200 may be disposed on one surface, for example, a rear surface, of the display panel 100. The heat dissipation layer 200 serves to dissipate heat generated from the display panel 100. The heat dissipation layer 130 may include a layer formed of graphite or metal such as, for example, silver (Ag), copper (Cu), or aluminum (Al) having high thermal conductivity.

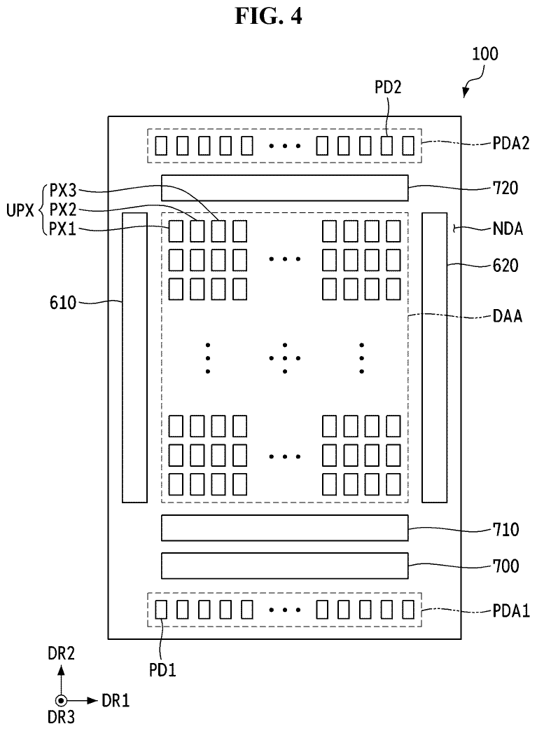

The circuit board 300 may be electrically connected to a plurality of first pads PD1 (see FIG. 4) of a first pad unit PDA1 (see FIG. 4) of the display panel 100 using a conductive adhesive member such as, for example, an anisotropic conductive film. The circuit board 300 may be a flexible printed circuit board or a flexible film having a flexible material. It has been illustrated in FIG. 1 that the circuit board 300 is unbent, but the circuit board 300 may be bent. In this case, one end of the circuit board 300 may be disposed on the rear surface of the display panel 100 and/or a rear surface of the heat dissipation layer 200. One end of the circuit board 300 may be an end opposite to the other end of the circuit board 300 connected to the plurality of first pads PD1 (see FIG. 4) of the first pad unit PDA1 (see FIG. 4) of the display panel 100 using the conductive adhesive member.

The timing controller 400 may receive digital video data and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610 and output the emission timing control signal ECS to the emission driver 620. The timing controller 400 may output the digital video data and the data timing control signal DCS to the data driver 700.

The power supply unit 500 may generate a plurality of panel driving voltages according to an external source voltage. For example, the power supply unit 500 may generate a common voltage VSS, a driving voltage VDD, and an initialization voltage VINT and supply the common voltage VSS, the driving voltage VDD, and the initialization voltage VINT to the display panel 100. The common voltage VSS, the driving voltage VDD, and the initialization voltage VINT will be described later with reference to FIG. 3.

Each of the timing controller 400 and the power supply unit 500 may be formed as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In some aspects, the common voltage VSS, the driving voltage VDD, and the initialization voltage VINT of the power supply unit 500 may be supplied to the display panel 100 through the circuit board 300.

Alternatively, each of the timing controller 400 and the power supply unit 500 may be disposed in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and formed on a semiconductor substrate SSUB (see FIG. 7). For example, the plurality of timing transistors and the plurality of power transistors may be formed as CMOSs. Each of the timing controller 400 and the power supply unit 500 may be disposed between the data driver 700 and the first pad unit PDA1 (see FIG. 4).

FIG. 3 is an equivalent circuit diagram of a first pixel according to an example embodiment.

Referring to FIG. 3, a first pixel PX1 may be connected to a write scan line GWL, a control scan line GCL, a bias scan line GBL, a first emission control line EL1, a second emission control line EL2, and a data line DL. In some aspects, the first pixel PX1 may be connected to a common voltage line VSL to which a common voltage VSS corresponding to a low potential voltage is applied, a driving voltage line VDL to which a driving voltage VDD corresponding to a high potential voltage is applied, and an initialization voltage line VIL to which an initialization voltage VINT is applied That is, the common voltage line VSL may be a low potential voltage line, the driving voltage line VDL may be a high potential voltage line, and the initialization voltage line VIL may be an initialization voltage line. In this case, the common voltage VSS may be a voltage lower than the initialization voltage VINT. The driving voltage VDD may be a voltage higher than the initialization voltage VINT.

The first pixel PX1 includes a plurality of transistors T1 to T6, a light emitting element LE, a first capacitor CP1, and a second capacitor CP2.

The light emitting element LE emits light according to a driving current Ids flowing through a channel of a first transistor T1. An amount of light emitted from the light emitting element LE may be proportional to the driving current Ids. The light emitting element LE may be disposed between a fourth transistor T4 and the common voltage line VSL. A first electrode of the light emitting element LE may be connected to a drain electrode of the fourth transistor T4, and a second electrode of the light emitting element LE may be connected to the common voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but embodiments of the present disclosure are not limited thereto. For example, the light emitting element LE may be an inorganic light emitting element including a first electrode, a second electrode, and an inorganic semiconductor disposed between the first electrode and the second electrode, and in this case, the light emitting element LE may be a micro light emitting diode.

The first transistor T1 may be a driving transistor controlling a source-drain current Ids (hereinafter referred to as a “driving current”) flowing between a source electrode and a drain electrode according to a voltage applied to a gate electrode of the first transistor T1. The first transistor T1 includes the gate electrode connected to a first node N1, the source electrode connected to a drain electrode of a sixth transistor T6, and the drain electrode connected to a second node N2.

A second transistor T2 may be disposed between one electrode of the first capacitor CP1 and the data line DL. The second transistor T2 is turned on by a write scan signal of the write scan line GWL to connect one electrode of the first capacitor CP1 to the data line DL. For this reason, a data voltage of the data line DL may be applied to one electrode of the first capacitor CP1. The second transistor T2 includes a gate electrode connected to the write scan line GWL, a source electrode connected to the data line DL, and a drain electrode connected to one electrode of the first capacitor CP1.

A third transistor T3 may be disposed between the first node N1 and the second node N2. The third transistor T3 is turned on by a control scan signal of the control scan line GCL to connect the first node N1 to the second node N2. For this reason, the gate electrode and the drain electrode of the first transistor T1 are connected to each other, and thus, the first transistor T1 may operate like a diode. The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. For this reason, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be disposed between the third node N3 and the initialization voltage line VIL. The fifth transistor T5 is turned on by a bias scan signal of the bias scan line GBL to connect the third node N3 to the initialization voltage line VIL. For this reason, the initialization voltage VINT of the initialization voltage line VIL may be applied to the first electrode of the light emitting element LE. The fifth transistor T5 includes a gate electrode connected to the bias scan line GBL, a source electrode connected to the third node N3, and a drain electrode connected to the initialization voltage line VIL.

The sixth transistor T6 may be disposed between the source electrode of the first transistor T1 and the driving voltage line VDL. The sixth transistor T6 is turned on by a second emission control signal of the second emission control line EL2 to connect the source electrode of the first transistor T1 to the driving voltage line VDL. For this reason, the driving voltage VDD of the driving voltage line VDL may be applied to the source electrode of the first transistor T1. The sixth transistor T6 includes a gate electrode connected to the second emission control line EL2, a source electrode connected to the driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the driving voltage line VDL. The second capacitor CP2 includes one electrode connected to the gate electrode of the first transistor T1 and the other electrode connected to the driving voltage line VDL.

The first node N1 is a contact point between the gate electrode of the first transistor T1, the drain electrode of the third transistor T3, the other electrode of the first capacitor CP1, and one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, some of the first to sixth transistors T1 to T6 may be P-type MOSFETs, and the others of the first to sixth transistors T1 to T6 may be N-type MOSFETs.

It has been illustrated in FIG. 3 that the first pixel PX1 includes six transistors Tl to T6 and two capacitors C1 and C2, but an equivalent circuit diagram of the first pixel PX1 is not limited to that illustrated in FIG. 3. For example, the numbers of transistors and capacitors of the first pixel PX1 are not limited to those illustrated in FIG. 3.

In some aspects, an equivalent circuit diagram of a second pixel PX2 and an equivalent circuit diagram of a third pixel PX3 may be substantially the same as the equivalent circuit diagram of the first pixel PX1 described with reference to FIG. 3. Therefore, a description of the equivalent circuit diagram of the second pixel PX2 and the equivalent circuit diagram of the third pixel PX3 is omitted in the present disclosure.

FIG. 4 is a layout diagram illustrating an example of a display panel according to an example embodiment.

Referring to FIG. 4, the display area DAA of the display panel 100 according to an example embodiment includes a plurality of pixels PX arranged in a matrix form. The non-display area NDA of the display panel 100 according to an example embodiment includes a scan driver 610, an emission driver 620, a data driver 700, a first distribution circuit 710, a second distribution circuit 720, a first pad unit PDA1, and a second pad unit PDA2.

The scan driver 610 may be disposed on a first side of the display area DAA, and the emission driver 620 may be disposed on a second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, embodiments of the present disclosure are not limited thereto, and the scan drivers 610 and the emission drivers 620 may be disposed on both the first and second sides of the display area DAA.

The first pad unit PDA1 may include a plurality of first pads PD1 connected to pads or bumps of the circuit board 300 through a conductive adhesive member. The first pad unit PDA1 may be disposed on a third side of the display area DAA. For example, the first pad unit PDA1 may be disposed on one side of the display area DAA in the second direction DR2.

The first pad unit PDA1 may be disposed outside the data driver 700 in the second direction DR2. That is, the first pad unit PDA1 may be disposed closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board formed of a rigid material or a flexible printed circuit board formed of a flexible material.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on a fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

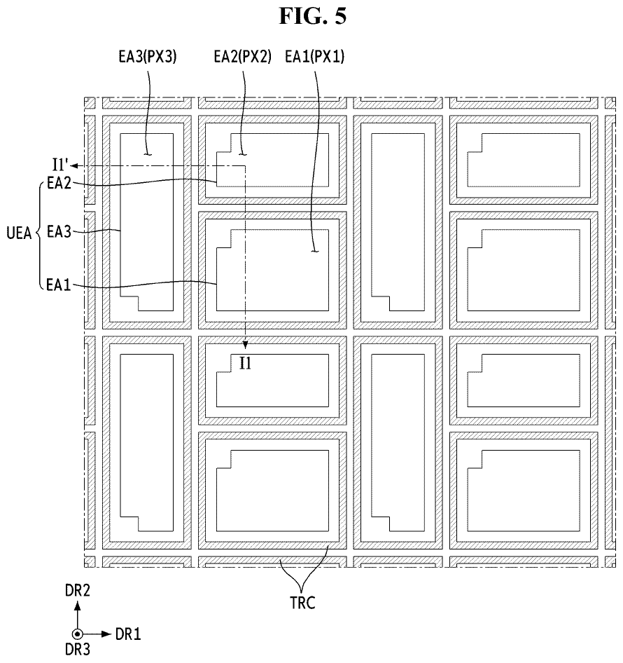

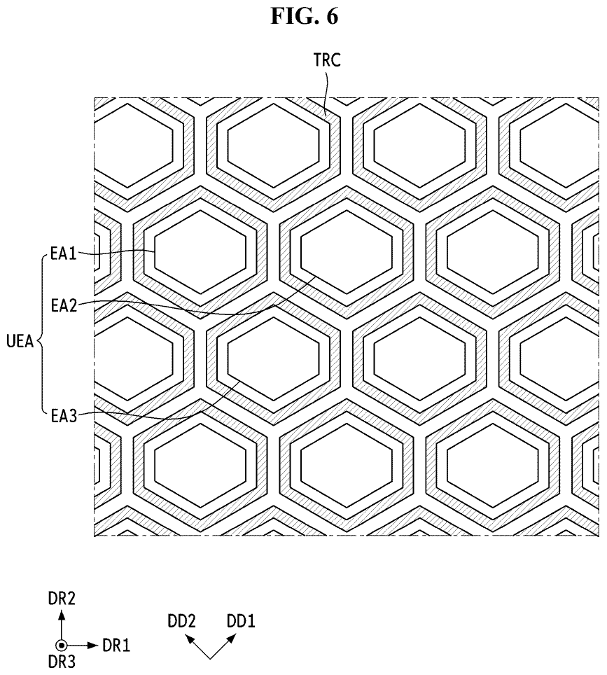

FIGS. 5 and 6 are layout diagrams illustrating example embodiments of a display area of FIG. 4.

Referring to FIGS. 5 and 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3. In other words, the unit pixel UPX may include a unit emission area UEA, and this unit emission area UEA includes the above-described first emission area EA1, second emission area EA2, and third emission area EA3.

Referring to FIGS. 5 and 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3.

Each of the first emission area EA1, the second emission area EA2, and the third emission area EA3 may have a polygonal shape, a circular shape, an elliptical shape, or an irregular shape in plan view.

A maximum length of the third emission area EA3 in the first direction DR1 may be smaller than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be substantially the same as each other.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be smaller than the maximum length of the third emission area EA3 in the second direction DR2.

Each of the first emission area EA1, the second emission area EA2, and the third emission area EA3 may have a hexagonal shape including six straight lines, in plan view, as illustrated in FIGS. 5 and 6, but embodiments of the present disclosure are not limited thereto. Each of the first emission area EA1, the second emission area EA2, and the third emission area EA3 may have polygonal shapes other than the hexagonal shape, a circular shape, an elliptical shape, or an irregular shape in plan view.

As illustrated in FIG. 5, in each of the plurality of pixels PX, the second emission area EA2 and the third emission area EA3 may neighbor to each other in the first direction DR1. In some aspects, the first emission area EA1 and the third emission area EA3 may neighbor to each other in the first direction DR1. In some aspects, the first emission area EA1 and the second emission area EA2 may neighbor to each other in the second direction DR2. An area of the first emission area EA1, an area of the second emission area EA2, and an area of the third emission area EA3 may be different from each other.

Alternatively, as illustrated in FIG. 6, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may indicate that a main peak wavelength of the light is included in a wavelength band of approximately 370 nm to 460 nm, the green wavelength band may indicate that a main peak wavelength of the light is included in a wavelength band of approximately 480 nm to 560 nm, and the red wavelength band may indicate that a main peak wavelength of the light is included in a wavelength band of approximately 600 nm and 750 nm.

It has been illustrated in FIGS. 5 and 6 that each of the plurality of unit pixels UPX includes three emission areas EA1, EA2, and EA3, but embodiments of the present disclosure are not limited thereto. That is, each of the plurality of unit pixels UPX may also include four emission areas.

In some aspects, an arrangement of the emission areas of the plurality of unit pixels UPX is not limited to those illustrated in FIGS. 5 and 6. For example, the emission areas of the plurality of unit pixels UPX may be disposed in a stripe structure in which the emission areas are arranged in the first direction DR1, a PenTile® structure in which the emission areas have a diamond arrangement, or a hexagonal structure in which emission areas having a hexagonal shape in plan view are arranged as illustrated in FIG. 6.

FIG. 7 is a cross-sectional view illustrating an example of the display panel taken along line I1-I1′ of FIG. 5.

Referring to FIG. 7, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with first-type impurities. A plurality of well regions WA may be disposed in an upper surface of the semiconductor substrate SSUB. The plurality of well regions WA may be regions doped with second-type impurities. The second-type impurities may be different from the first-type impurities described herein. In an example in which the first-type impurities are p-type impurities, the second-type impurities may be n-type impurities. Alternatively, when the first-type impurities are n-type impurities, the second-type impurities may be p-type impurities.

Each of the plurality of well regions WA includes a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region SA may be disposed on the other side of the gate electrode GE.

Each of the plurality of well regions WA further includes a first low-concentration impurity region LDD1 disposed between the channel region CH and the source region SA and a second low-concentration impurity region LDD2 disposed between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR may increase, and thus, punch-through and hot carrier phenomena caused by a short channel may be prevented.

A first semiconductor insulating film SINS1 may be disposed on the semiconductor substrate SSUB. The first semiconductor insulating film SINS1 may be formed as a silicon carbonitride (SiCN) or silicon oxide (SiOₓ)-based inorganic film, but embodiments of the present disclosure are not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but embodiments of the present disclosure are not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating through the first semiconductor insulating film SINS1 and the second semiconductor insulating film INS2. Each of the plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or alloys thereof.

A third semiconductor insulating film SINS3 may be disposed on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but embodiments of the present disclosure are not limited thereto.

The semiconductor substrate SSUB may be replaced with a glass substrate or a polymer resin substrate such as, for example, a polyimide substrate. In this case, thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP includes a plurality of conductive layers ML1 to ML8, a plurality of vias VA1 to VA9, and a plurality of insulating films INS1 to INS9. In some aspects, the light emitting element backplane EBP includes a plurality of insulating films INS1 to INS9 disposed between first to eighth conductive layers ML1 to ML8.

The first to eighth conductive layers ML1 to ML8 serve to implement a circuit of the first pixel PX1 illustrated in FIG. 3 by connecting the plurality of contact terminals CTE exposed from the semiconductor backplane SBP to each other. For example, the first to sixth transistors T1 to T6 are formed in the semiconductor backplane SBP, and the connection between the first to sixth transistors T1 to T6 and the formation of the first capacitor CP1 and the second capacitor CP2 are performed through the first to eighth conductive layers ML1 to ML8. In some aspects, the connection between a drain region corresponding to the drain electrode of the fourth transistor T4, a source region corresponding to the source electrode of the fifth transistor T5, and the first electrode of the light emitting element LE is also performed through the first to eighth conductive layers ML1 to ML8.

A first insulating film INS1 may be disposed on the semiconductor backplane SBP. Each of first vias VA1 may penetrate through the first film INS1 to be connected to the contact terminal CTE exposed from the semiconductor backplane SBP. Each of the first conductive layers ML1 may be disposed on the first insulating film INS1 and be connected to the first via VA1.

A second insulating film INS2 may be disposed on the first insulating film INS1 and the first conductive layers ML1. Each of second vias VA2 may penetrate through the second insulating film INS2 to be connected to the exposed first conductive layer ML1. Each of the second conductive layers ML2 may be disposed on the second insulating film INS2 and be connected to the second via VA2.

A third insulating film INS3 may be disposed on the second insulating film INS2 and the second conductive layers ML2. Each of third vias VA3 may penetrate through the third insulating film INS3 to be connected to the exposed second conductive layer ML2. Each of the third conductive layers ML3 may be disposed on the third insulating film INS3 and be connected to the third via VA3.

A fourth insulating film INS4 may be disposed on the third insulating film INS3 and the third conductive layer ML3. Each of fourth vias VA4 may penetrate through the fourth insulating film INS4 to be connected to the exposed third conductive layer ML3. Each of the fourth conductive layers ML4 may be disposed on the fourth insulating film INS4 and be connected to the fourth via VA4.

A fifth insulating film INS4 may be disposed on the fourth insulating film INS4 and the fourth conductive layers ML4. Each of fifth vias VA5 may penetrate through the fifth film INS5 to be connected to the exposed fourth conductive layer ML4. Each of the fifth conductive layers ML5 may be disposed on the fifth insulating film INS5 and be connected to the fifth via VA5.

A sixth insulating film INS6 may be disposed on the fifth insulating film INS5 and the fifth conductive layer ML5. Each of sixth vias VA6 may penetrate through the sixth insulating film INS6 to be connected to the exposed fifth conductive layer ML5. Each of the sixth conductive layers ML6 may be disposed on the sixth insulating film INS6 and be connected to the sixth via VA6.

A seventh insulating film INS7 may be disposed on the sixth insulating film INS6 and the sixth conductive layer ML6. Each of seventh vias VA7 may penetrate through the seventh insulating film INS7 to be connected to the exposed sixth conductive layer ML6. Each of the seventh conductive layers ML7 may be disposed on the seventh insulating film INS7 and be connected to the seventh via VA7.

An eighth insulating film INS8 may be disposed on the seventh insulating film INS7 and the seventh conductive layer ML7. Each of eighth vias VA8 may penetrate through the eighth insulating film INS8 to be connected to the exposed seventh conductive layer ML7. Each of the eighth conductive layers ML8 may be disposed on the eighth insulating film INS8 and be connected to the eighth via VA8.

The first to eighth conductive layers ML1 to ML8 and the first to eighth vias VA1 to VA8 may be formed of substantially the same material. Each of the first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or alloys thereof. The first to eighth vias VA1 to VA8 may be formed of substantially the same material. The first to eighth insulating films INS1 to INS8 may be formed as silicon oxide (SiOₓ)-based inorganic films, but embodiments of the present disclosure are not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the thickness of the eighth conductive layer ML8 may be approximately 9000 Å. Each of the thickness of the seventh via VA7 and the thickness of the eighth via VA8 may be approximately 6000 Å.

A ninth insulating film INS9 may be disposed on the eighth insulating film INS8 and the eighth conductive layer ML8. The ninth insulating film INS9 may be formed as a silicon oxide (SiOₓ)-based inorganic film, but embodiments of the present disclosure are not limited thereto.

Each of ninth vias VA9 may penetrate through the ninth insulating film INS9 to be connected to the exposed eighth conductive layer ML8. Each of the ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or alloys thereof. A thickness of the ninth via VA9 may be approximately 16500 Å.

The display element layer EML may be disposed on the light emitting element backplane EBP. The display element layer EML may include a reflective electrode layer RL, tenth and eleventh insulating films INS10 and INS11, tenth vias VA10, light emitting elements LE each including a first electrode AND, a light emitting stack ES, and a second electrode CAT, a pixel defining film PDL, and a plurality of trenches TRC.

The reflective electrode layer RL may be disposed on the ninth insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 7.

Each of the first reflective electrodes RL1 may be disposed on the ninth insulating film INS9 and be connected to the ninth via VA9. Each of the first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the first reflective electrodes RL1 may include titanium nitride (TiN).

Each of the second reflective electrodes RL2 may be disposed on the first reflective electrode RL1. Each of the second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the second reflective electrodes RL2 may include aluminum (Al).

Each of the third reflective electrodes RL3 may be disposed on the second reflective electrode RL2. Each of the third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the third reflective electrodes RL3 may include titanium nitride (TiN).

Each of the fourth reflective electrodes RL4 may be disposed on the third reflective electrode RL3. Each of the fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or alloys thereof. For example, each of the fourth reflective electrodes RL4 may include titanium (Ti).

Since the second reflective electrodes RL2 are electrodes substantially reflecting light from the light emitting elements LE, a thickness of the second reflective electrode RL2 may be greater than a thickness of the first reflective electrode RL1, a thickness of the third reflective electrode RL3, and a thickness of the fourth reflective electrode RL4. For example, each of the thickness of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be disposed on the reflective electrode layer RL in the third pixel PX3. The tenth insulating film INS10 may be formed as a silicon oxide (SiOₓ)-based inorganic film, but embodiments of the present disclosure are not limited thereto.

The eleventh insulating film INS11 may be disposed on the tenth insulating film INS10 and the reflective electrode layer RL. The eleventh insulating film INS11 may be formed as a silicon oxide (SiOₓ)-based inorganic film, but embodiments of the present disclosure are not limited thereto. The tenth insulating film INS10 and the eleventh insulating film INS11 may be optical auxiliary layers through which light reflected by the reflective electrode layer RL among light emitted from the light emitting elements LE passes.

In order to adjust a resonance distance of the light emitted from the light emitting elements LE in at least one of the first pixel PX1, the second pixel PX2, and the third pixel PX3, the tenth insulating film INS10 and the eleventh insulating film INS11 may not be disposed below the first electrode AND of the first pixel PX1. The first electrode AND of the first pixel PX1 may be directly disposed on the reflective electrode layer RL. The eleventh insulating film INS11 may be disposed below the first electrode AND of the second pixel PX2. The tenth insulating film INS10 and the eleventh insulating film INS11 may be disposed below the first electrode AND of the third pixel PX3.

In summary, a distance between the first electrode AND and the reflective electrode layer RL may be different in each of the first pixel PX1, the second pixel PX2, and the third pixel PX3. That is, in order to adjust a distance from the reflective electrode layer RL to the second electrode CAT according to a main wavelength of light emitted from each of the first pixel PX1, the second pixel PX2, and third the pixel PX3, the presence or absence of the tenth insulating film INS10 and the eleventh insulating film INS11 may be set in each of the first pixel PX1, the second pixel PX2, and the third pixel PX3. For example, it has been illustrated in FIG. 7 that a distance between the first electrode AND and the reflective electrode layer RL in the third pixel PX3 is greater than a distance between the first electrode AND and the reflective electrode layer RL in the second pixel PX2 and a distance between the first electrode AND and the reflective electrode layer RL in the first pixel PX1 and the distance between the first electrode AND and the reflective electrode layer RL in the second pixel PX2 is greater than the distance between the first electrode AND and the reflective electrode layer RL in the first pixel PX1, but embodiments of the present disclosure are not limited thereto.

In some aspects, the tenth insulating film INS10 and the eleventh insulating film INS11 have been illustrated in an example embodiment of the present disclosure, but a twelfth insulating film disposed below the first electrode AND of the first pixel PX1 may be added. In this case, the eleventh insulating film INS11 and the twelfth insulating film INS12 may be disposed below the first electrode AND of the second pixel PX2, and the tenth insulating film INS10, the eleventh insulating film INS11, and the twelfth insulating film INS12 may be disposed below the first electrode AND of the third pixel PX3.

Each of the tenth vias VA10 may penetrate through the tenth insulating film INS10 and/or the eleventh insulating film INS11 in the second pixel PX2 and the third pixel PX3 to be connected to the exposed fourth reflective electrode RL4. Each of the tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or alloys thereof. A thickness of the tenth via VA10 in the second pixel PX2 may be smaller than a thickness of the tenth via VA10 in the third pixel PX3.

The first electrode AND of each of the light emitting elements LE may be disposed on the tenth insulating film INS10 and be connected to the tenth via VA10. The first electrode AND of each of the light emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or alloys thereof. For example, the first electrode AND of each of the light emitting elements LE may be formed of titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the first emission areas EA1, the second emission areas EA2, and the third emission areas EA3.

The first emission area EA1 may be defined as an area where the first electrode AND, the light emitting stack ES, and the second electrode CAT are sequentially stacked in the first pixel PX1 to emit light. The second emission area EA2 may be defined as an area where the first electrode AND, the light emitting stack ES, and the second electrode CAT are sequentially stacked in the second pixel PX2 to emit light. The third emission area EA3 may be defined as an area where the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but embodiments of the present disclosure are not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film, a height of the one pixel defining film increases, such that a first encapsulation inorganic film TFE1 may be disconnected due to step coverage. The step coverage refers to a ratio of a degree at which a thin film is coated at an inclined portion of the thin film to a degree at which the thin film is coated at a flat portion of the thin film. The lower the step coverage, the more likely it is that the thin film will be disconnected at the inclined portion.

Therefore, in order to prevent the first encapsulation inorganic film TFE1 from being disconnected due to the step coverage, the first pixel defining film PDL1, the second pixel defining film PDL2, and the third pixel defining film PDL3 may have a cross-sectional structure with a step having a staircase shape. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length of the first pixel defining film PDL1 in a horizontal direction defined by the first direction DR1 and the second direction DR2.

Each of the plurality of trenches TRC may penetrate through the first pixel defining film PDL1, the second pixel defining film PDL2, and the third pixel defining film PDL3. In some aspects, each of the plurality of trenches TRC may penetrate through the eleventh insulating film INS11. In each of the plurality of trenches TRC, the tenth insulating film INS10 may have a shape in which a portion of the tenth insulating film INS10 is trenched.

At least one trench TRC may be disposed between the pixels PX1, PX2, and PX3 neighboring to each other. It has been illustrated in FIG. 7 that two trenches TRC are disposed between the pixels PX1, PX2, and PX3 neighboring to each other, but embodiments of the present disclosure are not limited thereto.

The light emitting stack ES may include a plurality of stack layers. It has been illustrated in FIG. 7 that the light emitting stack ES has a three-tandem structure including a first stack layer IL1, a second stack layer IL2, and a third stack layer IL3, but embodiments of the present disclosure are not limited thereto. For example, the light emitting stack ES may have a two-tandem structure including two intermediate layers.

In the three-tandem structure, the light emitting stack ES may have a tandem structure including a plurality of stack layers IL1, IL2, and IL3 emitting different light. For example, the light emitting stack ES may include a first stack layer IL1 emitting light of a first color, a second stack layer IL2 emitting light of a third color, and a third stack layer IL3 emitting light of a second color. The first stack layer IL1, the second stack layer IL2, and the third stack layer IL3 may be sequentially stacked.

The first stack layer IL1 may have a structure in which a first hole transporting layer, a first organic light emitting layer emitting the light of the first color, and a first electron transporting layer are sequentially stacked. The second stack layer IL2 may have a structure in which a second hole transporting layer, a second organic light emitting layer emitting the light of the third color, and a second electron transporting layer are sequentially stacked. The third stack layer IL3 may have a structure in which a third hole transporting layer, a third organic light emitting layer emitting the light of the second color, and a third electron transporting layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer supplying electrons to the first stack layer IL1 and a P-type charge generation layer supplying holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer supplying electrons to the second stack layer IL2 and a P-type charge generation layer supplying holes to the third stack layer IL3.

The first stack layer IL1 may be disposed on the first electrodes AND and the pixel defining film PDL, and may be disposed on a bottom surface of each of the trenches TRC. Due to the trenches TRC, the first stack layer IL1 may be disconnected between the pixels PX1, PX2, and PX3 neighboring to each other. The second stack layer IL2 may be disposed on the first stack layer IL1. Due to the trenches TRC, the second stack layer IL2 may be disconnected between the pixels PX1, PX2, and PX3 neighboring to each other. A cavity ESS or an empty space may be disposed between the first stack layer IL1 and the second stack layer IL2. The third stack layer IL3 may be disposed on the second stack layer IL2. The third stack layer IL3 may not be disconnected by the trenches TRC, and the third stack layer IL3 may be disposed such that third stack layer IL3 covers the second stack layer IL2 in each of the trenches TRC. That is, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 neighboring to each other. In some aspects, in the two-tandem structure, each of the plurality of trenches TRC may be a structure for disconnecting a charge generation layer disposed between a lower intermediate layer and an upper intermediate layer and the lower intermediate layer.

In order to stably disconnect the first and second stack layers IL1 and IL2 of the display element layer EML between the pixels PX1, PX2, and PX3 neighboring to each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second intermediate layers IL1 and IL2 of the display element layer EMTL between the pixels PX1, PX2, and PX3 neighboring to each other, other structures may exist instead of the trenches TRC. For example, instead of the trenches TRC, partition walls having a reverse tapered shape may be disposed on the pixel defining film PDL.

The number of stack layers IL1, IL2, and IL3 emitting the different light is not limited to that illustrated in FIG. 7. For example, the light emitting stack ES may include two intermediate layers. In this case, any one of the two intermediate layers may be substantially the same as the first stack layer IL1, and the other of the two intermediate layers may include a second hole transporting layer, a second organic light emitting layer, a third organic light emitting layer, and a second electron transporting layer. In this case, a charge generation layer for supplying electrons to any one intermediate layer and supplying charges to the other intermediate layer may be disposed between the two intermediate layers.

It has been illustrated in FIG. 7 that the first to third stack layers IL1, IL2, and IL3 are all disposed in the first emission area EA1, the second emission area EA2, and the third emission area EA3, but embodiments of the present disclosure are not limited thereto. For example, the first stack layer IL1 may be disposed in the first emission area EA1, and may not be disposed in the second emission area EA2 and the third emission area EA3. In some aspects, the second stack layer IL2 may be disposed in the second emission area EA2, and may not be disposed in the first emission area EA1 and the third emission area EA3. In some aspects, the third stack layer IL3 may be disposed in the third emission area EA3, and may not be disposed on the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as, for example, indium tin oxide (ITO) or indium zinc oxide (IZO) capable of transmitting light therethrough or a semi-transmissive conductive material such as, for example, magnesium (Mg), silver (Ag), or an alloy of magnesium (Mg) and silver (Ag). In an example in which the second electrode CAT is formed of the semi-transmissive conductive material, light emission efficiency of each of the first to third pixels PX1, PX2, and PX3 may be increased by a micro cavity.

The encapsulation layer TFE may be disposed on the display element layer EML. The encapsulation layer TFE may include at least one inorganic film TFE1 or TFE2 in order to prevent oxygen or moisture from permeating into the display element layer EML. For example, the encapsulation layer TFE may include a first encapsulation inorganic film TFE1 and a second encapsulation inorganic film TFE2.

The first encapsulation inorganic film TFE1 may be disposed on the second electrode CAT. The first encapsulation inorganic film TFE1 may be formed as multiple films in which one or more inorganic films of a silicon nitride (SiNₓ) layer, a silicon oxynitride (SiON) layer, and a silicon oxide (SiOₓ) layer are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed as a titanium oxide (TiOₓ) layer or an aluminum oxide (AlOₓ) layer, but embodiments of the present disclosure are not limited thereto. The second encapsulation inorganic film TFE2 may be formed by an atomic layer deposition (ALD) process. A thickness of the second encapsulation inorganic film TFE2 may be smaller than a thickness of the first encapsulation inorganic film TFE1.

An organic film APL may be a layer for increasing interfacial adhesive strength between the encapsulation layer TFE and the optical layer OPL. The organic film APL may be an organic film formed of an acrylic resin, an epoxy resin, a phenolic resin, a polyamide resin, a polyimide resin, or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on an adhesive layer ADL.

The first color filter CF1 may overlap the first emission area EA1 of the first pixel PX1. The first color filter CF1 may transmit the light of the first color, that is, light of a blue wavelength band, therethrough. The blue wavelength band may be approximately 370 nm to 460 nm. Therefore, the first color filter CF1 may transmit the light of the first color among light emitted from the first emission area EA1 therethrough.

The second color filter CF2 may overlap the second emission area EA2 of the second pixel PX2. The second color filter CF2 may transmit the light of the second color, that is, light of a green wavelength band, therethrough. The green wavelength band may be approximately 480 nm to 560 nm. Therefore, the second color filter CF2 may transmit the light of the second color among light emitted from the second emission area EA2 therethrough.

The third color filter CF3 may overlap the third emission area EA3 of the third pixel PX3. The third color filter CF3 may transmit the light of the third color, that is, light of a red wavelength band, therethrough. The blue wavelength band may be approximately 600 nm to 750 nm. Therefore, the third color filter CF3 may transmit the light of the third color among light emitted from the third emission area EA3 therethrough.

Each of the plurality of lenses LNS may be disposed on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction.

The filling layer FIL may be disposed on the plurality of lenses LNS. The filling layer FIL may have a predetermined refractive index such that light travels in the third direction DR3 at an interface between the plurality of lenses LNS and the filling layer FIL. In some aspects, the filling layer FIL may be a planarizing layer. The filling layer FIL may be an organic film formed of an acrylic resin, an epoxy resin, a phenolic resin, a polyamide resin, a polyimide resin, or the like.

The cover layer CVL may be disposed on the filling layer FIL. The cover layer CVL may be a glass substrate or a resin such as, for example, a polymer resin. In an example in which the cover layer CVL is the glass substrate, the cover layer CVL may be attached onto the filling layer FIL. In this case, the filling layer FIL may serve to adhere the cover layer CVL. In an example in which the cover layer CVL is the glass substrate, the cover layer CVL may serve as an encapsulation substrate. In an example in which the cover layer CVL is a resin such as, for example, a polymer resin, the cover layer CVL may be directly applied onto the filling layer FIL.

The polarizing plate POL may be disposed on one surface of the cover layer CVL. The polarizing plate POL may be a structure for preventing deterioration in visibility due to external light reflection. The polarizing plate POL may include a linear polarizing plate and a phase retardation film. For example, the phase retardation film may be a λ/4 plate (quarter-wave plate), but embodiments of the present disclosure are not limited thereto. However, when visibility due to external light reflection is sufficiently improved by the first to third color filters CF1, CF2, and CF3, the polarizing plate POL may be omitted.

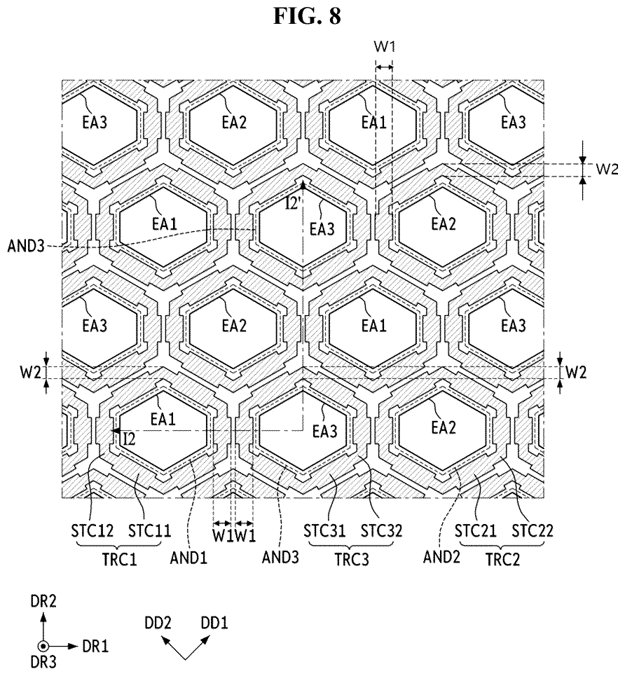

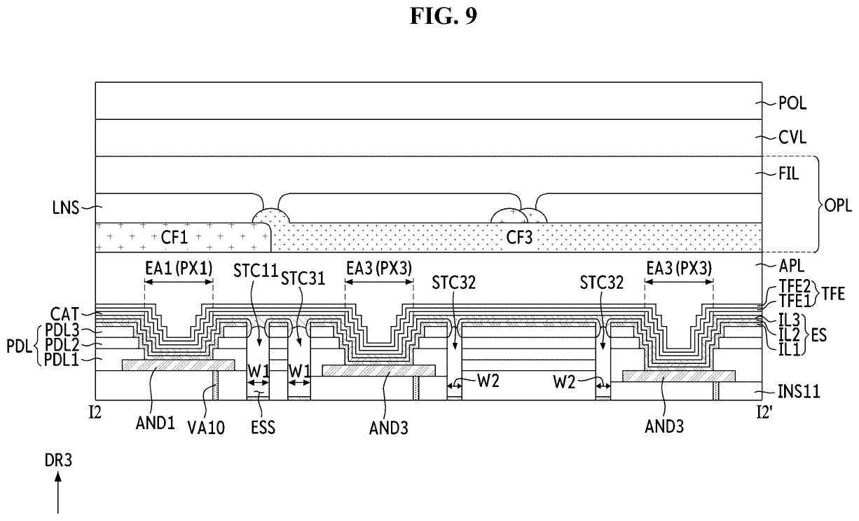

FIG. 8 is a layout diagram illustrating another example embodiment of the display area of FIG. 4, and FIG. 9 is a cross-sectional view illustrating an example embodiment of the display panel taken along line I1-I1′ of FIG. 8. In some embodiments, a structure disposed below the eleventh insulating film INS11 described herein with reference to FIG. 7 may be disposed below an eleventh insulating film INS11 of FIG. 9. For example, the reflective electrode layer RL, the light emitting element backplane EBP, and the semiconductor backplane SBP may be sequentially disposed below the eleventh insulating film INS11 in FIG. 9 along a direction reverse to the third direction DR3.

Another example embodiment of FIGS. 8 and 9 is different from the example embodiment described herein with reference to FIGS. 5, 6, and 7 in shapes of trenches TRC, and such differences will be mainly described herein.

As illustrated in FIG. 8, in plan view, each of first electrodes (hereinafter referred to as anode electrodes, for example, anode electrodes AND1, AND2, and AND3 in FIG. 8) may have a hexagonal shape. However, a shape of each of the anode electrodes AND1, AND2, and AND3 is not limited thereto, and may be of any various shape supportive of a display panel 100 described herein. In some aspects, in plan view, an edge of each of the anode electrodes AND1, AND2, and AND3 may have a shape of a closed curve surrounding each of emission areas. A plurality of anode electrodes AND1, AND2, and AND3 may include first anode electrodes AND1 disposed and respectively corresponding to the first emission areas EA1, second anode electrodes AND2 disposed and respectively corresponding to the second emission areas EA2, and third anode electrodes AND3 disposed and respectively corresponding to the third emission areas EA3.

As illustrated in FIG. 8, in plan view, each of the emission areas (e.g., plurality of emission areas EA1, EA2, and EA3) may have a hexagonal shape. However, a shape of the emission area is not limited thereto, and may be of any various shape supportive of a display panel 100 described herein. A plurality of emission areas EA1, EA2, and EA3 illustrated in FIG. 8 may include first emission areas EA1 providing light of a first color, second emission areas EA2 providing light of a second color, and third emission areas EA3 providing light of a third color. For example, as described herein, the light of the first color may be light of a blue wavelength band, the light of the second color may be light of a green wavelength band, and the light of the third color may be light of a red wavelength band.

As illustrated in FIG. 8, in plan view, each of the trenches TRC1, TRC2, and TRC3 may have a hexagonal shape. However, a shape of each of the trenches TRC1, TRC2, and TRC3 is not limited thereto, and may be of any various shape supportive of a display panel 100 described herein. In some aspects, in plan view, each of the trenches TRC1, TRC2, and TRC3 may have a shape of a closed curve surrounding each of the emission areas EA1, EA2, and EA3 and each of the anode electrodes AND1, AND2, and AND3.

Each trench surrounding a given emission area may have different widths. For example, the trenches TRC1, TRC2, and TRC3 may include, respectively, first sub-trenches STC11, STC21, and STC31 and second sub-trenches STC12, STC22, and SCT32, and widths of the first sub-trenches STC11, STC21, and STC31 may be different from widths of the second sub-trenches STC12, STC22, and SCT32. Specifically, a first trench TRC1 surrounding the first emission area EA1 providing the light of the first color may include a first sub-trench STC11 and a second sub-trench STC12 that have different respective widths, a second trench TRC2 surrounding the second emission area EA2 providing the light of the second color may include a first sub-trench STC21 and a second sub-trench STC22 that have different respective widths, and a third trench TRC3 surrounding the third emission area EA3 providing the light of the third color may include a first sub-trench STC31 and a second sub-trench STC32 that have different respective widths. According to an example embodiment, a width W1 of the first sub-trench STC11 may be greater than a width W2 of the second sub-trench STC12.

According to an example embodiment, the first sub-trench STC11 of the first trench TRC1 may be disposed between emission areas that provide light of different respective colors.

For example, in plan view, one portion (hereinafter referred to as a first portion) of the first trench TRC1 surrounding the first emission area EA1 may be disposed between the first emission area EA1 and the second emission area EA2 (or the third emission area EA3) adjacent to the first emission area EA1. In other words, the first portion of the first trench TRC1 surrounding the first emission area EA1 may be disposed between the first emission area EA1 and the second emission area EA2 (or the third emission area EA3) that neighbor to each other and provide light of different respective colors, and may be the first sub-trench STC11 of the first trench TRC1.

The term “adjacent” herein may refer to elements which are relatively close to each other (e.g., within a threshold distance, neighbor each other) or elements which are in contact with each other. For example, for an emission area (e.g., first emission area EA1) described as adjacent to another emission area (e.g., second emission area EA2), another emission area is not present between the adjacent emission areas.

As a specific example embodiment, each side of the first trench TRC1 may face the second emission area EA2 (or the third emission area EA3), and each center side of each side of the first trench TRC1 excluding both edges of each side of the first trench TRC1 may be defined as the first sub-trench STC11 of the first trench TRC1.

As a more specific example embodiment, when a side of the first trench TRC1 facing the second emission area EA2 (or the second trench TRC2) adjacent in the first diagonal direction DD1 in the first diagonal direction DD1 among the sides of the first trench TRC1 is defined as a first side of the first trench TRC1, a side of the first trench TRC1 facing the third emission area EA3 (or the third trench TRC3) adjacent in the first direction DR1 in the first direction DR1 among the sides of the first trench TRC1 is defined as a second side of the first trench TRC1, a side of the first trench TRC1 facing the second emission area EA2 (or the second trench TRC2) adjacent in a direction reverse to the second diagonal direction DD2 (hereinafter referred to as a second reverse diagonal direction) in the second reverse diagonal direction among the sides of the first trench TRC1 is defined as a third side of the first trench TRC1, a side of the first trench TRC1 facing the third emission area EA3 (or the third trench TRC3) adjacent in a direction reverse to the first diagonal direction DD1 (hereinafter referred to as a first reverse diagonal direction) in the first reverse diagonal direction among the sides of the first trench TRC1 is defined as a fourth side of the first trench TRC1, a side of the first trench TRC1 facing the second emission area EA2 (or the second trench TRC2) adjacent in a direction reverse to the first direction DR1 (hereinafter referred to as a first reverse direction) in the first reverse direction among the sides of the first trench TRC1 is defined as a fifth side of the first trench TRC1, and a side of the first trench TRC1 facing the third emission area EA3 (or the third trench TRC3) adjacent in the second diagonal direction DD2 in the second diagonal direction DD2 among the sides of the first trench TRC1 is defined as a sixth side of the first trench TRC1, the first, second, third, fourth, fifth, and sixth sides of the first trench TRC1 may each include a first sub-trench STC11, and the first, second, third, fourth, fifth, and sixth sides of the first trench TRC1 may each include a portion of a second sub-trench STC12. For example, each of the center sides of the first to sixth sides of the first trench TRC1 excluding both edges of the first to sixth sides of the first trench TRC1 may be defined as the first sub-trench STC11 of the first trench TRC1. In other words, a central portion of each side of the first trench TRC1 may include the first sub-trench STC11. Specifically, each of a central portion of the first side, a central portion of the second side, a central portion of the third side, a central portion of the fourth side, a central portion of the fifth side, and a central portion of the sixth side of the first trench TRC1 may be defined as the first sub-trench STC11 of the first trench TRC1.

According to an example embodiment, the second sub-trench STC12 of the first trench TRC1 may be disposed between emission areas that provide light of the same color.

For example, in plan view, another portion (hereinafter referred to as a second portion) of the first trench TRC1 surrounding the first emission area EA1 may be disposed between the first emission area EA1 and another first emission area EA1 adjacent to the first emission area EA1. In other words, the second portion of the first trench TRC1 surrounding the first emission area EA1 may be disposed between the first emission areas EA1 that neighbor to each other and provide light of the same color, and may be the second sub-trench STC12 of the first trench TRC1.

As a specific example embodiment, respective bent portions of the first trench TRC1 surrounding the first emission area EA1 may face the other two first emission areas EA1 (or first trenches TRC1), and each of the bent portions of the first trench TRC1 excluding the central portion of each side of the first trench TRC1 may be defined as the second sub-trench STC12 of the first trench TRC1. In other words, the second sub-trenches STC12 of the first trench TRC1 may include portions excluding the central portion of the first side, the central portion of the second side, the central portion of the third side, the central portion of the fourth side, the central portion of the fifth side, and the central portion of the sixth side of the first trench TRC1 described herein.

As a more specific example embodiment, when a bent portion of the first trench TRC1 facing the first emission area EA1 (or the first trench TRC1) adjacent in the second direction DR2 in the second direction DR2, of the bent portions of the first trench TRC1 is defined as a first bent portion of the first trench TRC1 and a bent portion of the first trench TRC1 facing the first emission area EA1 (or the first trench TRC1) adjacent in a direction reverse to the second direction DR2 (hereinafter referred to as a second reverse direction) in the second reverse direction, of the bent portions of the first trench TRC1 is defined as a second bent portion of the first trench TRC1, each of the first bent portion and the second bent portion of the first trench TRC1 may include the second sub-trench STC12. For example, each of the first bent portion and the second bent portion of the first trench TRC1 may be defined as the second sub-trench STC12 of the first trench TRC1.

The second sub-trench STC12 of the first trench TRC1 may include a corner. In this case, a corner of the second sub-trench STC12 provided in any one of two first trenches TRC1 adjacent to each other in the second direction DR2 may face a corner of the second sub-trench STC12 provided in the other of the two first trenches TRC1 adjacent to each other in the second direction DR2.

The first sub-trench STC11 of the first trench TRC1 surrounding the first emission area EA1 may have a greater width than the second sub-trench STC12 of the first trench TRC1 (W1>W2). For example, the width W1 of the first sub-trench STC11 provided in the first trench TRC1 may be greater than the width W2 of the second sub-trench STC12 provided in the first trench TRC1.

According to an example embodiment, each second sub-trench STC12 may be disposed between emission areas that provide light of different respective colors.

For example, in plan view, one portion (hereinafter referred to as a first portion) of the second trench TRC2 surrounding the second emission area EA2 may be disposed between the second emission area EA2 and the first emission area EA1 (or the third emission area EA3) adjacent to the second emission area EA2. In other words, the first portion of the second trench TRC2 surrounding the second emission area EA2 may be disposed between the second emission area EA2 and the first emission area EA1 (or the third emission area EA3) that neighbor to each other and provide light of different respective colors, and may be the first sub-trench STC21 of the second trench TRC2.

As a specific example embodiment, each side of the second trench TRC2 may face the first emission area EA1 (or the third emission area EA3), and each center side of each side of the second trench TRC2 excluding both edges of each side of the second trench TRC2 may be defined as the first sub-trench STC11 of the second trench TRC2.

As a more specific example embodiment, when a side of the second trench TRC2 facing the third emission area EA3 (or the third trench TRC3) adjacent in the first diagonal direction DD1 in the first diagonal direction DD1 among the sides of the second trench TRC2 is defined as a first side of the second trench TRC2, a side of the second trench TRC2 facing the first emission area EA1 (or the first trench TRC1) adjacent in the first direction DR1 in the first direction DR1 among the sides of the second trench TRC2 is defined as a second side of the second trench TRC2, a side of the second trench TRC2 facing the third emission area EA3 (or the third trench TRC3) adjacent in the second reverse diagonal direction in the second reverse diagonal direction among the sides of the second trench TRC2 is defined as a third side of the second trench TRC2, a side of the second trench TRC2 facing the first emission area EA1 (or the first trench TRC1) adjacent in the first reverse diagonal direction in the first reverse diagonal direction among the sides of the second trench TRC2 is defined as a fourth side of the second trench TRC2, a side of the second trench TRC2 facing the third emission area EA3 (or the third trench TRC3) adjacent in the first reverse direction in the first reverse direction among the sides of the second trench TRC2 is defined as a fifth side of the second trench TRC2, and a side of the second trench TRC2 facing the first emission area EA1 (or the first trench TRC1) adjacent in the second diagonal direction DD2 in the second diagonal direction DD2 among the sides of the second trench TRC2 is defined as a sixth side of the second trench TRC2, the first, second, third, fourth, fifth, and sixth sides of the second trench TRC2 may each include a first sub-trench STC21, and the first, second, third, fourth, fifth, and sixth sides of the second trench TRC2 may each include a portion of a second sub-trench STC22. For example, each of the center sides of the first to sixth sides of the second trench TRC2 excluding both edges of the first to sixth sides of second trench TRC2 may be defined as the first sub-trench STC21 of the second trench TRC2. In other words, a central portion of each side of the second trench TRC2 may include the first sub-trench STC21. Specifically, each of a central portion of the first side, a central portion of the second side, a central portion of the third side, a central portion of the fourth side, a central portion of the fifth side, and a central portion of the sixth side of the second trench TRC2 may be defined as the first sub-trench STC21 of the second trench TRC2.

In some embodiments, the second sub-trench STC22 of the second trench TRC2 may be disposed between emission areas that provide light of the same color.

For example, in plan view, another portion (hereinafter referred to as a second portion) of the second trench TRC2 surrounding the second emission area EA2 may be disposed between the second emission area EA2 and another second emission area EA2 adjacent to the second emission area EA2. In other words, the second portion of the second trench TRC2 surrounding the second emission area EA2 may be disposed between the second emission areas EA2 that neighbor to each other and provide light of the same color, and may be the second sub-trench STC22 of the second trench TRC2.

As a specific example embodiment, respective bent portions of the second trench TRC2 surrounding the second emission area EA2 may face the other two second emission areas EA2 (or second trenches TRC2), and each of the bent portions of the second trench TRC2 excluding the central portion of each side of the second trench TRC2 may be defined as the second sub-trench STC22 of the second trench TRC2. In other words, the second sub-trenches STC22 of the second trench TRC2 may include portions excluding the central portion of the first side, the central portion of the second side, the central portion of the third side, the central portion of the fourth side, the central portion of the fifth side, and the central portion of the sixth side of the second trench TRC2 described herein.

As a more specific example embodiment, when a bent portion of the second trench TRC2 facing the second emission area EA2 (or the second trench TRC2) adjacent in the second direction DR2 in the second direction DR2, of the bent portions of the second trench TRC2 is defined as a first bent portion of the second trench TRC2 and a bent portion of the second trench TRC2 facing the second emission area EA2 (or the second trench TRC2) adjacent in the second reverse direction in the second reverse direction, of the bent portions of the second trench TRC2 is defined as a second bent portion of the second trench TRC2, each of the first bent portion and the second bent portion of the second trench TRC2 may include the second sub-trench STC22. For example, each of the first bent portion and the second bent portion of the second trench TRC2 may be defined as the second sub-trench STC22 of the second trench TRC2.

The second sub-trench STC22 of the second trench TRC2 may include a corner. In this case, a corner of the second sub-trench STC22 provided in any one of two second trenches TRC2 adjacent to each other in the second direction DR2 may face a corner of the second sub-trench STC22 provided in the other of the two second trenches TRC2 adjacent to each other in the second direction DR2.

The first sub-trench STC21 of the second trench TRC2 surrounding the second emission area EA2 may have a greater width than the second sub-trench STC22 of the second trench TRC2. For example, a width W1 of the first sub-trench STC21 provided in the second trench TRC2 may be greater than a width W2 of the second sub-trench STC22 provided in the second trench TRC2.

According to an example embodiment, the first sub-trench STC31 of the third trench TRC3 may be disposed between emission areas that provide light of different respective colors.

For example, in plan view, one portion (hereinafter referred to as a first portion) of the third trench TRC3 surrounding the third emission area EA3 may be disposed between the third emission area EA3 and the first emission area EA1 (or the second emission area EA2) adjacent to the third emission area EA3. In other words, the first portion of the third trench TRC3 surrounding the third emission area EA3 may be disposed between the third emission area EA3 and the first emission area EA1 (or the second emission area EA2) that neighbor to each other and provide light of different respective colors, and may be the first sub-trench STC31 of the third trench TRC3.

As a specific example embodiment, each side of the third trench TRC3 may face the first emission area EA1 (or the second emission area EA2), and each center side of each side of the third trench TRC3 excluding both edges of each side of the third trench TRC3 may be defined as the first sub-trench STC31 of the third trench TRC3.

As a more specific example embodiment, when a side of the third trench TRC3 facing the first emission area EA1 (or the first trench TRC1) adjacent in the first diagonal direction DD1 in the first diagonal direction DD1 among the sides of the third trench TRC3 is defined as a first side of the third trench TRC3, a side of the third trench TRC3 facing the second emission area EA2 (or the second trench TRC2) adjacent in the first direction DR1 in the first direction DR1 among the sides of the third trench TRC3 is defined as a second side of the third trench TRC3, a side of the third trench TRC3 facing the first emission area EA1 (or the first trench TRC1) adjacent in the second reverse diagonal direction in the second reverse diagonal direction among the sides of the third trench TRC3 is defined as a third side of the third trench TRC3, a side of the third trench TRC3 facing the second emission area EA2 (or the second trench TRC2) adjacent in the first reverse diagonal direction in the first reverse diagonal direction among the sides of the third trench TRC3 is defined as a fourth side of the third trench TRC3, a side of the third trench TRC3 facing the first emission area EA1 (or the first trench TRC1) adjacent in the first reverse direction in the first reverse direction among the sides of the third trench TRC3 is defined as a fifth side of the third trench TRC3, and a side of the third trench TRC3 facing the second emission area EA2 (or the second trench TRC2) adjacent in the second diagonal direction DD2 in the second diagonal direction DD2 among the sides of the third trench TRC is defined as a sixth side of the third trench TRC3, the first, second, third, fourth, fifth, and sixth sides of the third trench TRC3 may each include the first sub-trench STC31, and the first, second, third, fourth, fifth, and sixth sides of the third trench TRC3 may each include a portion of a second sub-trench STC32. For example, each of the center sides of the first to sixth sides of the third trench TRC3 excluding both edges of the first to sixth sides of third trench TRC3 may be defined as the first sub-trench STC31 of the third trench TRC3. In other words, a central portion of each side of the third trench TRC3 may include the first sub-trench STC31. Specifically, each of a central portion of the first side, a central portion of the second side, a central portion of the third side, a central portion of the fourth side, a central portion of the fifth side, and a central portion of the sixth side of the third trench TRC3 may be defined as the first sub-trench STC31 of the third trench TRC3.

In some embodiments, the second sub-trench STC32 of the third trench TRC3 may be disposed between emission areas that provide light of the same color.

For example, in plan view, another portion (hereinafter referred to as a second portion) of the third trench TRC3 surrounding the third emission area EA3 may be disposed between the third emission area EA3 and another third emission area EA3 adjacent to the third emission area EA3. In other words, the second portion of the third trench TRC3 surrounding the third emission area EA3 may be disposed between the third emission areas EA3 that neighbor to each other and provide light of the same color, and may be the second sub-trench STC32 of the third trench TRC3.

As a specific example embodiment, respective bent portions of the third trench TRC3 surrounding the third emission areas EA3 may face the other two third emission areas EA3 (or third trenches TRC3), and each of the bent portions of the third trench TRC3 excluding the central portion of each side of the third trench TRC3 may be defined as the second sub-trench STC32 of the third trench TRC3. In other words, the second sub-trenches STC32 of the third trench TRC3 may include portions excluding the central portion of the first side, the central portion of the second side, the central portion of the third side, the central portion of the fourth side, the central portion of the fifth side, and the central portion of the sixth side of the third trench TRC3 described herein.

As a more specific example embodiment, when a bent portion of the third trench TRC3 facing the third emission area EA3 (or the third trench TRC3) adjacent in the second direction DR2 in the second direction DR2, of the bent portions of the third trench TRC3 is defined as a first bent portion of the third trench TRC3 and a bent portion of the third trench TRC3 facing the third emission area EA3 (or the third trench TRC3) adjacent in the second reverse direction in the second reverse direction, of the bent portions of the third trench TRC3 is defined as a second bent portion of the third trench TRC3, each of the first bent portion and the second bent portion of the third trench TRC3 may include the second sub-trench STC32. For example, each of the first bent portion and the second bent portion of the third trench TRC3 may be defined as the second sub-trench STC32 of the third trench TRC3.

The second sub-trench STC32 of the third trench TRC3 may include a corner. In this case, a corner of the second sub-trench STC32 provided in any one of two third trenches TRC3 adjacent to each other in the second direction DR2 may face a corner of the second sub-trench STC32 provided in the other of the two third trenches TRC3 adjacent to each other in the second direction DR2.

The first sub-trench STC31 of the third trench TRC3 surrounding the third emission area EA3 may have a greater width than the second sub-trench STC32 of the third trench TRC3. For example, a width W1 of the first sub-trench STC31 provided in the third trench TRC3 may be greater than a width W2 of the second sub-trench STC32 provided in the third trench TRC3.

According to an example embodiment, first sub-trenches of the same trench may have the same width. For example, six first sub-trenches STC11 of the first trench TRC1 may have the same width, six first sub-trenches STC21 of the second trench TRC2 may have the same width, and six first sub-trenches STC31 of the third trench TRC3 may have the same width.

According to an example embodiment, the first sub-trenches of each of the trenches TRC1, TRC2, and TRC3 may have the same width. For example, the first sub-trench STC11 of the first trench TRC1, the first sub-trench STC21 of the second trench TRC2, and the first sub-trench STC31 of the third trench TRC3 may have the same width.

According to an example embodiment, second sub-trenches of the same trench may have the same width. For example, two second sub-trenches STC12 of the first trench TRC1 may have the same width, two second sub-trenches STC22 of the second trench TRC2 may have the same width, and two second sub-trenches STC32 of the third trench TRC3 may have the same width.

According to an example embodiment, the second sub-trenches of each of the trenches TRC1, TRC2, and TRC3 may have the same width. For example, the second sub-trench STC12 of the first trench TRC1, the second sub-trench STC22 of the second trench TRC2, and the second sub-trench STC32 of the third trench TRC3 may have the same width.

According to an example embodiment, the light emitting stack ES and the second electrode CAT (e.g., a cathode electrode) may be disconnected at the first sub-trenches STC11, STC21, and STC31 having a relatively great width W1. In some embodiments, the light emitting stack ES and the second electrode CAT (e.g., the cathode electrode) may not be disconnected at the second sub-trenches STC12, STC22, and STC32 having a relatively small width W2. Here, as described herein, the disconnection of the light emitting stack ES may mean that the first and second stack layers IL1 and IL2, the first charge generation layer, and the second charge generation layer of the light emitting stack ES are disconnected.

According to an example embodiment, the first sub-trenches respectively included in the trenches adjacent to each other may overlap color filters of different respective colors. For example, as illustrated in FIG. 9, the first sub-trench STC11 of the first trench TRC1 may overlap the first color filter CF1, and the first sub-trench STC31 of the third trench TRC3 may overlap the third color filter CF3.

According to an example embodiment, the second sub-trenches respectively included in the trenches adjacent to each other may overlap a color filter of the same color. For example, as illustrated in FIG. 9, each of the second sub-trench STC32 of the third trench TRC3 on the left and the second sub-trench STC32 of the third trench TRC3 on the right may overlap the third color filter CF3.

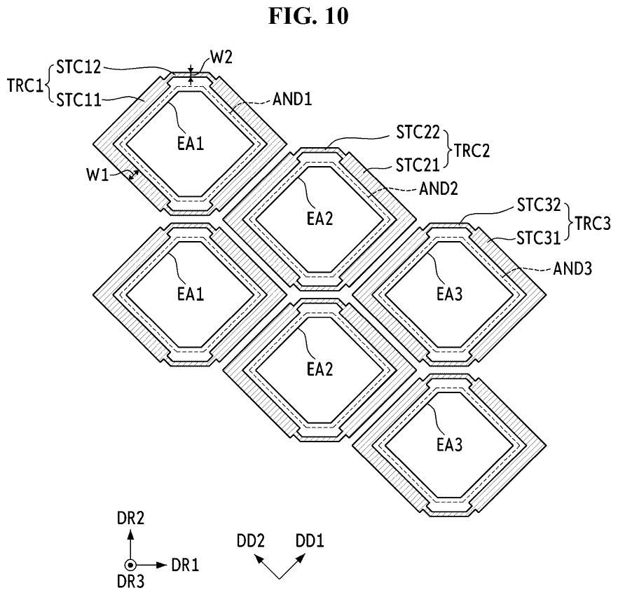

FIG. 10 is a layout diagram illustrating still another example embodiment of the display area of FIG. 4.

Still another example embodiment of FIG. 10 is different from another example embodiment described herein with reference to FIGS. 8 and 9 in shapes of trenches, and such differences will be mainly described herein.

As illustrated in FIG. 10, each trench surrounding a given emission area may have different widths. For example, each of the trenches TRC1, TRC2, and TRC3 may include a first sub-trench and a second sub-trench that have different respective widths. For example, a first trench TRC1 surrounding the first emission area EA1 providing the light of the first color may include a first sub-trench STC11 and a second sub-trench STC12 that have different respective widths, a second trench TRC2 surrounding the second emission area EA2 providing the light of the second color may include a first sub-trench STC21 and a second sub-trench STC22 that have different respective widths, and a third trench TRC3 surrounding the third emission area EA3 providing the light of the third color may include a first sub-trench STC31 and a second sub-trench STC32 that have different respective widths. According to an example embodiment, a width W1 of the first sub-trench STC11 may be greater than a width W2 of the second sub-trench STC12.

Each first sub-trench STC11 may be disposed between emission areas that provide light of different respective colors.

Each second sub-trench STC21 may be disposed between emission areas that provide light of the same color.

In plan view, the first sub-trench STC11 of each of the trenches TRC1, TRC2, and TRC3 may have a bent shape. For example, the first sub-trench STC11 of the first trench TRC1 may include two portions (also referred to herein as two sides) and one corner formed by connecting the two portions (two sides) to each other. According to an example embodiment, the first sub-trench STC11 of the first trench TRC1 may have a shape of “<” or a shape of “>”.

In plan view, the second sub-trench STC12 of each of the trenches TRC1, TRC2, and TRC3 may have a bent shape. For example, the second sub-trench STC12 of the first trench TRC1 may include three portions (e.g., a long portion, a first short portion, and a second short portion) and two corners (hereinafter referred to as a first corner and a second corner). The three portions (e.g., a long portion, a first short portion, and a second short portion) may also be referred to as three sides (e.g., a long side, a first short side, and a second short side). In this case, the first corner may be formed at a portion where two neighboring portions (e.g., the first short portion and the long portion) of the three portions are connected to each other, and the second corner may be formed at a portion where two neighboring portions (e.g., the second short portion and the long portion) of the three portions are connected to each other. Here, long portions of neighboring second sub-trenches STC12 may face each other.

In an example in which an upper first trench TRC1 of two first trenches TRC1 respectively surrounding two first emission areas EA1 in FIG. 10 is defined as a first-first trench and a lower first trench TRC1 of the two first trenches TRC1 is defined as a first-second trench, a long portion of a second sub-trench STC12 provided in the first-first trench and a long portion of a second sub-trench STC12 provided in the first-second trench may be disposed such that the long portions face each other.

In some embodiments, as illustrated in FIG. 10, emission areas that provide the light of the same color may be arranged along the second direction DR2. For example, the first emission areas EA1 may be arranged along the second direction DR2 in a first column, the second emission areas EA2 may be arranged along the second direction DR2 in a second column, and the third emission areas EA3 may be arranged along the second direction DR2 in a third column.

According to an example embodiment, the first sub-trench (e.g., STC11; hereinafter referred to as a wide sub-trench) between the emission areas that provide the light of the different colors may have a greater width the second sub-trench (e.g., STC12; hereinafter referred to as narrow sub-trench) between the emission areas that provide the light of the same color. Accordingly, the light emitting stack ES may be more easily disconnected at the wide sub-trench, and disconnection of the second electrode CAT (e.g., the cathode electrode) on the narrow sub-trench may be prevented.

In some aspects, the wide sub-trench is disposed between the emission areas that provide the light of the different colors, and accordingly, a problem that light (e.g., the light of the different colors) from different emission areas is mixed may be solved due to the increased width of the wide sub-trench.

In some aspects, the narrow sub-trench is disposed between the emission areas that provide the light of the same color, and accordingly, a problem of color mixing may not occur even though the light emitting stack is not disconnected at the narrow sub-trench due to a small width of the narrow sub-trench. In this case, even though the second electrode CAT is disconnected at the wide sub-trench, the second electrode is not disconnected at the narrow sub-trench, and thus, resistance of the second electrode may be compensated for by the narrow sub-trench such that an increase in the resistance is prevented or mitigated.

As described herein, according to the display device 10 according to an example embodiment, color mixing between adjacent emission areas that provide the light of the different colors may be prevented and disconnection of the second electrode CAT on adjacent emission areas that provide the light of the same color may be prevented.

In some embodiments, a depth of the first sub-trench may be greater than a depth of the second sub-trench. Here, the depth may be, for example, a size in the third direction. For example, in FIG. 9, the first sub-trench may penetrate through the pixel defining film PDL and the eleventh insulating film INS11, and the second sub-trench may penetrate through the pixel defining film PDL. In other words, the second sub-trench may penetrate through the first pixel defining film PDL, the second pixel defining film PDL, and the third pixel defining film PDL, but may not penetrate through the eleventh insulating film INS11. Accordingly, the first sub-trench penetrating through the first pixel defining film PDL, the second pixel defining film PDL, the third pixel defining film PDL, and the eleventh insulating film INS11 may have a greater depth than the second sub-trench. In such a case, as described herein, the light emitting stack ES may be more easily disconnected at the wide sub-trench, and the disconnection of the second electrode CAT (e.g., the cathode electrode) on the narrow sub-trench may be prevented.

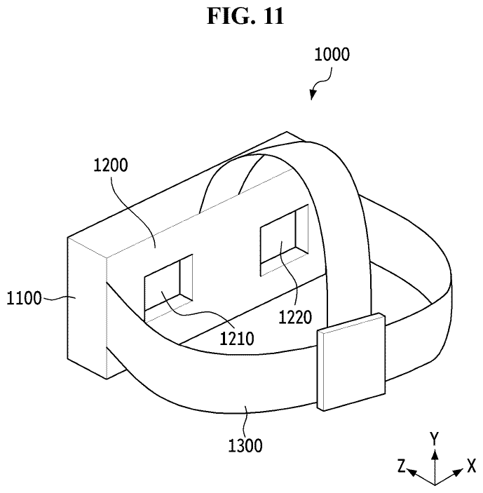

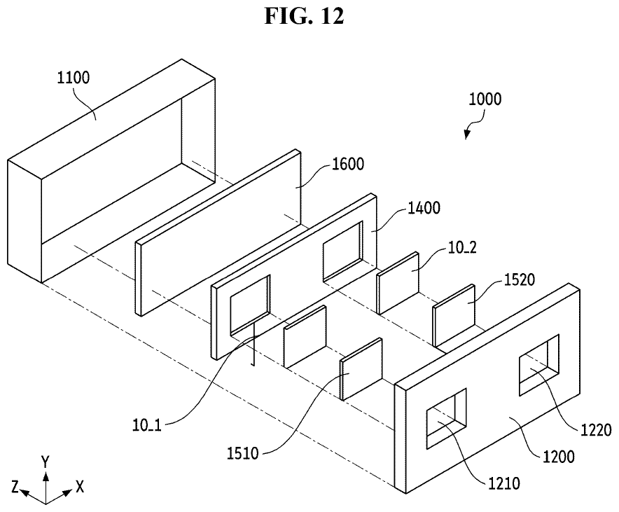

FIG. 11 is a perspective view illustrating a head mounted display according to an example embodiment. FIG. 12 is an exploded perspective view illustrating an example of the head mounted display of FIG. 11.

Referring to FIGS. 11 and 12, a head mounted display device 1000 according to an example embodiment includes a first display device 10_1, a second display device 10_2, a display device housing portion 1100, a housing portion cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 to 10, and a description of the first display device 10_1 and the second display device 10_2 is thus omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing portion 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

The control circuit board 1600 may transmit digital video data DATA corresponding to a left eye image optimized for the user's left eye to the first display device 10_1 and transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing portion 1100 serves to house the first display device 10_1, the second display device 10_2, the middle frame 1400, the first optical member 1510, the second optical member 1520, and the control circuit board 1600. The housing portion cover 1200 is disposed such that the housing portion cover 1200 covers an opened surface of the display device housing portion 1100. The housing portion cover 1200 may include the first eyepiece 1210 on which the user's left eye is disposed and the second eyepiece 1220 on which the user's right eye is disposed. It has been illustrated in FIGS. 11 and 12 that the first eyepiece 1210 and the second eyepiece 1220 are separately disposed, but embodiments of the present disclosure are not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

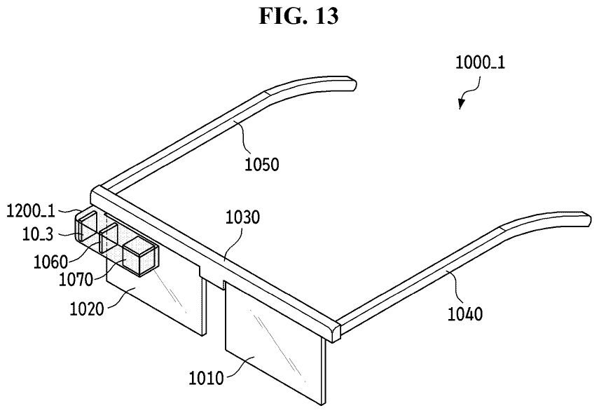

The head mounted band 1300 serves to fix the display device housing portion 1100 to a user's head such that the first eyepiece 1210 and the second eyepiece 1220 of the housing portion cover 1200 may be maintained in a state where they are disposed on the user's left eye and right eye, respectively. In an example in which the display device housing portion cover 1200 is implemented to have a light weight and a small size, the head mounted display device 1000 may include an eyeglass frame as illustrated in FIG. 13 instead of the head mounted band 800.

In some aspects, the head mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 13 is a perspective view illustrating a head mounted display according to another example embodiment.

Referring to FIG. 13, a head mounted display device 1000_1 according to another example embodiment may be a glasses-type display device in which a display device housing portion 1200_1 is implemented to have a light weight and a small size. The head mounted display device 1000_1 according to another example embodiment may include a display device 10_3, a left eye lens 1010, a right eye lens 1020, a support frame 1030, glasses frame legs 1040 and 1050, an optical member 1060, an optical path conversion member 1070, and a display device housing portion 1200_1.

The display device housing portion 1200_1 may include the display device 10_3, the optical member 1060, and the optical path conversion member 1070. An image displayed on the display device 10_3 may be magnified by the optical member 1060, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 13 that the display device housing portion 1200_1 is disposed at a right end of the support frame 1030, but embodiments of the present disclosure are not limited thereto. For example, the display device housing portion 1200_1 may be disposed at a left end of the support frame 1030, and in this case, an image of the display device 10_3 may be provided to a user's left eye. Alternatively, the display device housing portions 1200_1 may be disposed at both the left and right ends of the support frame 1030, and in this case, the user may view an image displayed on the display device 10_3 through both his/her left and right eyes.

However, the effects of the present disclosure are not restricted to the one set forth herein. The above and other effects of the present disclosure will become more apparent to one of daily skill in the art to which the present disclosure pertains by referencing the claims.

It will be able to be understood by one of ordinary skill in the art to which the present disclosure belongs that the present disclosure may be implemented in other specific forms without changing the technical spirit or essential features of the present disclosure. Therefore, it is to be understood that the example embodiments described herein are illustrative rather than being restrictive in all aspects. It is to be understood that the scope of the present disclosure are defined by the claims rather than the detailed description described herein and all modifications and alterations derived from the claims and their equivalents fall within the scope of the present disclosure.

What is claimed is:

1. A display device comprising:
a substrate;
a plurality of first electrodes disposed on the substrate;
a pixel defining film disposed on the plurality of first electrodes and defining a plurality of emission areas respectively overlapping the plurality of first electrodes, wherein the pixel defining film is disposed on a plurality of trenches adjacent to the plurality of emission areas;
a light emitting stack disposed on the plurality of first electrodes and overlapping the plurality of emission areas; and
a second electrode disposed on the light emitting stack,
wherein:
the plurality of trenches each comprise a first sub-trench and a second sub-trench that have different respective widths,
the first sub-trench is disposed between adjacent emission areas that provide light of different respective colors, and
the second sub-trench is disposed between adjacent emission areas that provide light of a same color.

2. The display device of claim 1, wherein the width of the first sub-trench is greater than the width of the second sub-trench.

3. The display device of claim 1, wherein the light emitting stack and the second electrode are disconnected at the first sub-trench.

4. The display device of claim 1, wherein the light emitting stack and the second electrode are not disconnected at the second sub-trench.

5. The display device of claim 1, wherein the plurality of emission areas comprise a first emission area, a second emission area, and a third emission area that provide light of different respective colors.

6. The display device of claim 5, wherein the plurality of trenches comprise:
a first trench surrounding the first emission area;
a second trench adjacent to the first emission area and surrounding the second emission area; and
a third trench adjacent to the first emission area and the second emission area and surrounding the third emission area.

7. The display device of claim 6, wherein the first sub-trench of the first trench is disposed between the first emission area and the second emission area.

8. The display device of claim 6, wherein the first sub-trench of the first trench is disposed between the first emission area and the third emission area.

9. The display device of claim 6, wherein the second sub-trench of the first trench is disposed between the first emission area and another first emission area adjacent to the first emission area.

10. The display device of claim 6, wherein:
the first trench has a polygonal shape, and
the first sub-trench of the first trench is disposed at a side of the first trench.

11. The display device of claim 6, wherein:
the first trench has a polygonal shape, and
the second sub-trench of the first trench is disposed at a corner of the first trench.

12. The display device of claim 6, wherein the first sub-trench of the second trench is disposed between the second emission area and the first emission area.

13. The display device of claim 6, wherein the first sub-trench of the second trench is disposed between the second emission area and the third emission area.

14. The display device of claim 6, wherein the second sub-trench of the second trench is disposed between the second emission area and another second emission area adjacent to the second emission area.

15. The display device of claim 6, wherein:
the second trench has a polygonal shape, and
the first sub-trench of the second trench is disposed at a side of the second trench.

16. The display device of claim 6, wherein:
the second trench has a polygonal shape, and
the second sub-trench of the second trench is disposed at a corner of the second trench.

17. The display device of claim 6, wherein the first sub-trench of the third trench is disposed between the third emission area and the first emission area.

18. The display device of claim 6, wherein the first sub-trench of the third trench is disposed between the third emission area and the second emission area.

19. The display device of claim 6, wherein the second sub-trench of the third trench is disposed between the third emission area and another third emission area adjacent to the third emission area.

20. The display device of claim 6, wherein:
the third trench has a polygonal shape, and
the first sub-trench of the third trench is disposed at a side of the third trench.

21. The display device of claim 6, wherein:
the third trench has a polygonal shape, and
the second sub-trench of the third trench is disposed at a corner of the third trench.

22. The display device of claim 1, wherein the first sub-trench has a rectangular shape.

23. The display device of claim 1, wherein the second sub-trench has a bent shape.

24. The display device of claim 1, wherein:
the first sub-trench has a bent shape, and
the first sub-trench has one bent portion.

25. The display device of claim 1, wherein:
the second sub-trench has a bent shape, and
the second sub-trench has two bent portions.

26. An electronic device comprising:
a display device including a screen;
wherein the display device comprising:
a substrate;
a plurality of first electrodes disposed on the substrate;
a pixel defining film disposed on the plurality of first electrodes and defining a plurality of emission areas respectively overlapping the plurality of first electrodes, wherein the pixel defining film is disposed on a plurality of trenches adjacent to the plurality of emission areas;
a light emitting stack disposed on the plurality of first electrodes and overlapping the plurality of emission areas; and
a second electrode disposed on the light emitting stack,
wherein:
the plurality of trenches each comprise a first sub-trench and a second sub-trench that have different respective widths,
the first sub-trench is disposed between adjacent emission areas that provide light of different respective colors, and
the second sub-trench is disposed between adjacent emission areas that provide light of a same color.
